(19) United States
(12) Patent Application Publication
(10) Pub. No.: US 2024/0371439 A1
(43) Pub. Date: Nov. 7, 2024

(54) RANDOM ACCESS MEMORY APPARATUS, MEMORY SYSTEM, AND METHOD FOR OPERATING THE SAME

(71) Applicant: TAIWAN SEMICONDUCTOR MANUFACTURING COMPANY LTD., HSINCHU (TW)

(72) Inventors: JUI-JEN WU, HSINCHU (TW); YU-SHENG CHEN, TAOYUAN CITY (TW); YI CHING ONG, HSINCHU (TW); MENG-FAN CHANG, TAICHUNG CITY (TW); KUEN-YI CHEN, HSINCHU CITY (TW); JEN-CHIEH LIU, HSINCHU (TW); TAI-HAO WEN, NEW TAIPEI CITY (TW); KUO-CHING HUANG, HSINCHU CITY (TW)

(21) Appl. No.: 18/312,564

(22) Filed: May 4, 2023

(51) Int. Cl. G11C 13/00

(52) U.S. Cl. CPC G11C 13/004; G11C 13/0026; G11C 13/0028; G11C 13/0069; G11C 2213/79

(57) ABSTRACT

A resistive random access memory (ReRAM) apparatus is provided. The ReRAM apparatus includes a plurality of memory cells, each of the memory cells comprises a transistor and a resistor; a bit line connected to a first terminal of the resistor of each of the memory cells; a local source line connected to a source electrode of the transistor of each of the memory cells; and a driving cell connected between the local source line and a global source line. A method for operating the ReRAM apparatus is also provided.

### BACKGROUND

The present disclosure relates to memory apparatus, and more particularly, to driving cells in a resistive random access memory array.

Nonvolatile memory elements are used in systems in which persistent storage is required. As device dimensions shrink, scaling issues are posing challenges for traditional nonvolatile memory technology. This has led to the investigation of alternative nonvolatile memory technologies, including resistive switching nonvolatile memory. Resistive memory apparatus, e.g., resistive switching nonvolatile random access memory (ReRAM) is formed using memory cells that have two or more stable states with different resistances. Bistable memory has two stable states. A bistable memory cell can be placed in a high resistance state or a low resistance state by applying suitable voltages or currents. Voltage pulses or current flows are typically used to switch the memory cell from one resistance state to the other. Nondestructive read operations can be performed to ascertain the value of a data bit that is stored in a memory cell.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, dimensions of the various features may be arbitrarily increased or reduced for clarity of discussion.

FIG. 1 is a schematic diagram of a memory system, in accordance with some embodiments of the present disclosure.

FIG. 2 is a schematic diagram of a ReRAM apparatus, in accordance with some embodiments of the present disclosure.

FIG. 3 is a time diagram of signals in a memory system, in accordance with some embodiments of the present disclosure.

FIG. 4 is a schematic diagram of a ReRAM apparatus, in accordance with some embodiments of the present disclosure.

FIG. 5 is a flow chart of a method for operating a ReRAM apparatus, in accordance with some embodiments of the present disclosure.

FIG. 6 is a time diagram of signals in a memory system, in accordance with some embodiments of the present disclosure.

FIG. 7 is a schematic diagram of a ReRAM apparatus, in accordance with some embodiments of the present disclosure.

FIG. 8 is a flow chart of a method for operating a ReRAM apparatus, in accordance with some embodiments of the present disclosure.

FIG. 9 is a time diagram of signals in a memory system, in accordance with some embodiments of the present disclosure.

FIG. 10 is a schematic diagram of a ReRAM apparatus, in accordance with some embodiments of the present disclosure.

FIG. 11 is a flow chart of a method for operating a ReRAM apparatus, in accordance with some embodiments of the present disclosure.

FIG. 12 is a time diagram of signals in a memory system, in accordance with some embodiments of the present disclosure.

FIG. 13 is a schematic diagram of a ReRAM apparatus, in accordance with some embodiments of the present disclosure.

FIG. 14 is a flow chart of a method for operating a ReRAM apparatus, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially.” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially.” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

For a ReRAM system, the reading speed is relatively slow because it is difficult for a small read current of the memory cell to drive the heavy loading of a long source line. The improvement of the read current is a big challenge for the memory devices due to the small read current and large RC parasitic of the read source line. Reducing parasitic capacitance is related to memory cell area and the cell node connections, which involve the fundamental problems and it is not easy to improve the reading speed.

When the ReRAM system performs a read operation, the selected word line turns on the read current of the target memory cell, and the read current will flow into the sense amplifier through the read source line. The read source line of the memory usually connects multiple memory cells to achieve good area efficiency. When more memory cells are connected on the read source line, the RC loading of the read source line is larger and results in a slow reading speed. It will take a long time for propagating the read current to the sense amplifier for the read operation due to the large RC loading of the read source line, which make the reading speed very slow.

In some embodiments of the present disclosure, the long source line is divided into a plurality of smaller segments (i.e., short local source lines) so as to reduce the heavy loading, and thus the small read current only need to drive a lighter loading of the local source line. Fewer memory cells (e.g., 16 memory cells) share a proposed two transistor (2T) driving cell for current amplification, and to use the amplified current to drive the long global source line to improve the reading speed. In some embodiments of the present disclosure, since the 2T driving cell is shared by 16 cells, the cell area penalty for the present disclosure is small. Additionally, since the signals of the global source line for sensing have been amplified by the 2T driving cell, the sense amplifier may have large read margin, and the required offset tolerance of the sense amplifier can be improved.

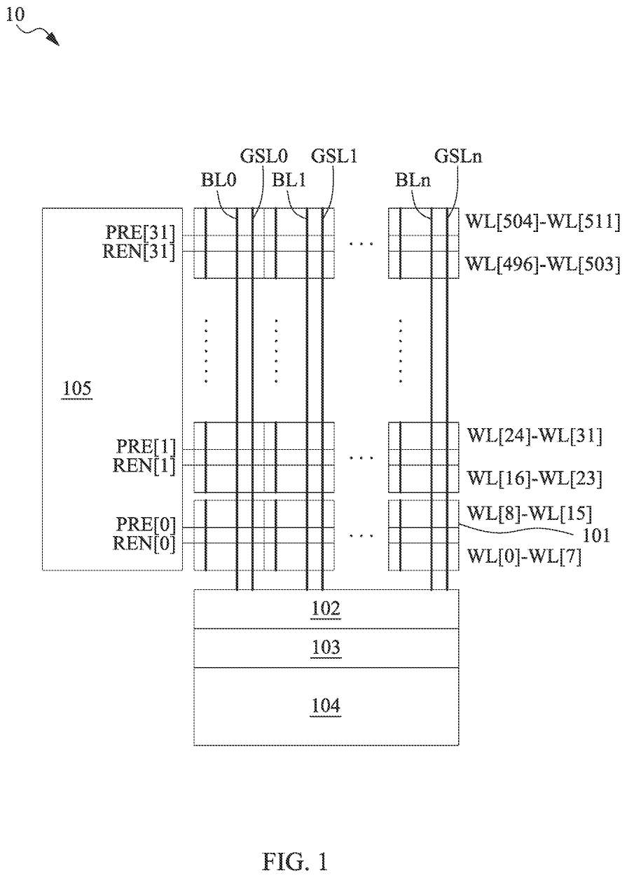

FIG. 1 is a schematic diagram of a memory system 10, in accordance with some embodiments of the present disclosure. In some embodiments of the present disclosure, a memory system 10 comprises: bit lines BL0-BLn, global source lines GSL0-GSLn, word lines [0]-[504], a plurality of ReRAM apparatuses 101, a global source line multiplexer 102. a bit line multiplexer 103, a sense amplifier 104, a driving cell controller 105, a plurality of preset lines PRE[0]-PRE[31] and a plurality of read-enable lines REN[0]-REN[31].

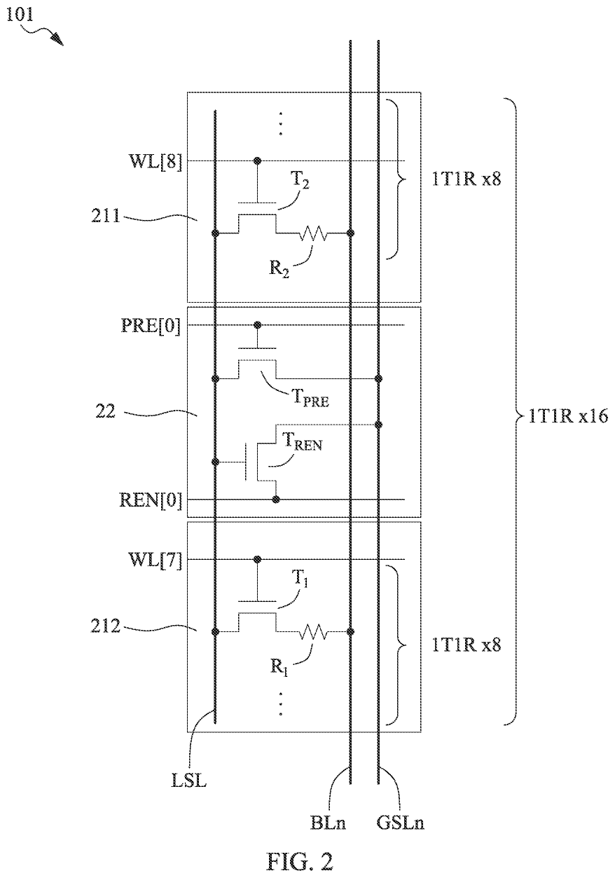

FIG. 2 is a schematic diagram of a ReRAM apparatus 101, in accordance with some embodiments of the present disclosure. In some embodiments of the present disclosure, the ReRAM apparatus 101 comprises: a first group of memory cells 211, a second group of memory cells 212, a local source line LSL, a driving cell 22, a preset line PRE[0], a read-enable line REN[0], a bit lines BLn, a global source lines GSLn and word lines WL[0]-[15]. As shown in FIG. 2, one memory cell of the second group of memory cells 212 comprises a transistor T1 and a resistor R1. A first terminal of the resistor R1 is connected to the bit line BLn. The drain electrode of the transistor T1 is connected to a second terminal of the resistor R1. The local source line LSL is connected to the source electrode of the transistor T1. The driving cell 22 is connected between the local source line LSL and the global source line GSLn. In some embodiments of the present disclosure, the plurality of memory cells 101 are arranged into an array.

Referring back to FIG. 1, in some embodiments of the present disclosure, the global source lines GSL0-GSLn are connected to the global source line multiplexer 102. In some embodiments of the present disclosure, the bit lines BL0-BLn are connected to the bit line multiplexer 103. The global source line multiplexer 102 and the bit line multiplexer 103 help select between the signals on the global source lines GSL0-GSLn and the bit lines BL0-BLn, and forward the selected input to a single or fewer output lines.

In some embodiments of the present disclosure, the global source line GSLn is connected to a sense amplifier 104 as shown in FIG. 1. In some embodiments of the present disclosure, a sense amplifier 104 is part of a read circuitry that is used when data is read from the memory apparatus. The role of the sense amplifier 104 is to sense the low power signals from a source line that represents a data bit (“1” or “0”) stored in a memory cell, and to amplify the small voltage swing to a recognizable level so that the data can be interpreted properly by a logic circuit outside the memory apparatus.

In some embodiments of the present disclosure, another memory cell of the first group of memory cells 211 comprises a transistor T2 and a resistor R2. The configurations of the transistor T2 and the resistor R2 are similar to those of the transistor T1 and the resistor R1.

In some embodiments of the present disclosure, the first group of memory cells 211 comprises eight memory cells. Each of the eight memory cells comprises one transistor and one resistor and thus can be referred to as a “1T1R” memory cell. The second group of memory cells 212 can also comprises eight memory cells. In some embodiments of the present disclosure, the number of the memory cells in the first group of memory cells 211 and the second group of memory cells 212 can be any positive integers fewer or more than eight. The ReRAM apparatus 101 in FIG. 2 comprises 16 “1T1R” memory cells. In some embodiments of the present disclosure, the ReRAM apparatus may comprises fewer or more than 16 memory cells. However, as the number of the memory cells in the ReRAM apparatus become larger, the local source line will also become longer so that the reading speed may still be restricted. In some embodiments of the present disclosure, the first group of memory cells 211 and the second group of memory cells 212 may have different numbers of memory cells. In some embodiments of the present disclosure, one of the first group of memory cells 211 and the second group of memory cells 212 may have zero memory cells and all of the memory cells are in the other group of memory cells.

In some embodiments of the present disclosure, the driving cell 22 comprises a preset transistor T_{PRE} and a read-enable transistor T_{REN}. The drain electrode of the preset transistor T_{PRE} is connected to the local source line LSL of the ReRAM apparatus 101. The source electrode of the preset transistor T_{PRE} is connected to the global source line GSLn. The gate electrode of the read-enable transistor T_{REN} is connected to the local source line LSL of the ReRAM apparatus 101. The source electrode of the read-enable transistors T_{REN} is connected to the global source line GSLn.

In some embodiments of the present disclosure, the preset line PRE[0] is connected to the gate electrode of the preset transistor T_{PRE} of the ReRAM apparatus 101. In some embodiments of the present disclosure, the read-enable line REN[0] is connected to the drain electrode of the read-enable transistor T_{REN} of the ReRAM apparatus 101. In some embodiments of the present disclosure, the gate electrode of the transistor of each of the memory cells is connected to a respective one of the plurality of word lines WL[0]-[15].

In some embodiments of the present disclosure, the preset line PRE[0] and the read-enable line REN[0] in FIG. 2 are connected and controlled by the driving cell controller 105 as shown in FIG. 1.

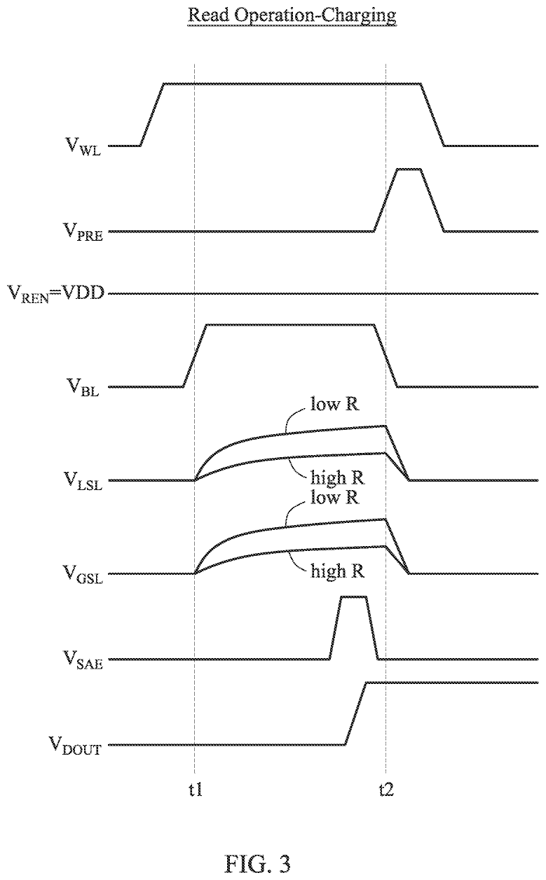

FIG. 3 is a time diagram of signals in a memory system in accordance with some embodiments of the present disclosure. FIG. 3 shows a read operation of a ReRAM apparatus 101 comprising a plurality of memory cells as shown in FIG. 2. In the read operation, first of all, the read-enable voltage V_{REN} of a read-enable line is set to a first voltage level VDD. The read-enable line is connected to a drain electrode of a read-enable transistor of the ReRAM apparatus. The word line voltage V_{WL} of a word line of the plurality of word lines of the ReRAM apparatus is also set to the first voltage level VDD. The word line is connected to a gate electrode of a transistor of a memory cell of the plurality of memory cells. Then, at time t1, the bit line voltage V_{BL} of a bit line of the ReRAM apparatus is set to the first voltage level VDD. The bit line is connected to a first terminal of a resistor of a memory cell of the plurality of memory cells. A second terminal of the resistor is connected to a drain electrode of the transistor.

Since the word line is connected to the gate electrode of the transistor and the word line voltage V_{WL} is set to the first voltage level VDD, the transistor should be turned on in response to setting the word line and the bit line. A first current flows from the bit line through the resistor and the transistor to a local source line connected to a source electrode of the transistor and a gate electrode of the read-enable transistor. The local source line is then charged.

In some embodiments of the present disclosure, if the memory cell is in a low resistance state (low R), the first current should be relatively large so that the local source line voltage V_{LSL} of the local source line can be charged quickly. As the local source line voltage V_{LSL} being charged to a threshold voltage level of the read-enable transistor, the read-enable transistor is turned on. Therefore, in response to charging the voltage of the local source line, a second current flows from the read-enable line through the read-enable transistor to a global source line connected to the source electrode of the read-enable transistor. The global source line is then charged. Finally, an enable voltage V_{SAE} of a sense amplifier is set to the first voltage level VDD. The global source line voltage V_{GSL} of the global source line is then sensed by the sense amplifier, and the sense amplifier outputs a data output voltage V_{DOUT}. Finally, at time t2, the bit line voltage V_{BL} of the bit line is set to zero and the preset voltage V_{PRE} of a preset line is set to the first voltage level VDD. The preset line is connected to the gate electrode of a preset transistor so that the preset transistor is turned on and creates a current path between the local source line and the global source line. Since the bit line is set to zero, both the local source line and the global source line are discharged to zero.

In some embodiments of the present disclosure, if the memory cell is in a high resistance state (high R), the first current should be relatively small so that the local source line voltage V_{LSL} of the local source line is charged slowly. As the local source line voltage V_{LSL} being charged to the threshold voltage level of the read-enable transistor, the read-enable transistor is turned on. Therefore, in response to charging the voltage of the local source line, the second current flows from the read-enable line through the read-enable transistor to the global source line connected to the source electrode of the read-enable transistor. The global source line is then charged. However, since the local source line voltage V_{LSL} in the high resistance state is lower than the local source line voltage V_{LSL} in the low resistance state, the global source line voltage V_{GSL} of the global source line is charged in a much slower speed. Then, an enable voltage V_{SAE} of a sense amplifier is set to the first voltage level VDD. The global source line voltage V_{GSL} of the global source line is then sensed by the sense amplifier, and the sense amplifier outputs a data output voltage V_{DOUT}. Finally, at time t2, the bit line voltage V_{BL} of the bit line is set to zero and the preset voltage V_{PRE} of a preset line is set to the first voltage level VDD. The preset line is connected to the gate electrode of a preset transistor so that the preset transistor is turned on and creates a current path between the local source line and the global source line. Since the bit line is set to zero, both the local source line and the global source line are discharged to zero.

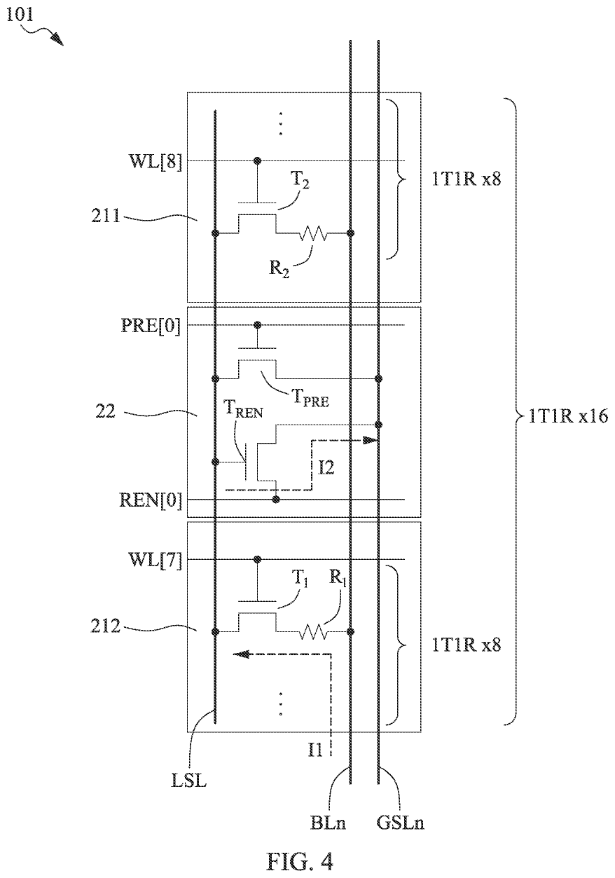

FIG. 4 is a schematic diagram of a ReRAM apparatus, in accordance with some embodiments of the present disclosure. FIG. 4 shows the current flows in the ReRAM apparatus 101 as shown in FIG. 2 during the read operation as mentioned in FIG. 3. Since the word line WL[7] is connected to the gate electrode of the transistor T1 and the word line voltage V_{WL} is set to the first voltage level VDD as shown in FIG. 3, the transistor T1 is turned on. The first current I1 flows from the bit line BLn through the resistor R1 and the transistor T1, to the local source line LSL connected to the source electrode of the transistor T1 and a gate electrode of the read-enable transistor T_{REN}.

Additionally, as the local source line voltage V_{LSL} being charged to a threshold voltage level of the read-enable transistor T_{REN}, the read-enable transistor T_{REN} is turned on. Therefore, in response to charging the voltage of the local source line LSL, the second current I2 flows from the read-enable line REN[0] through the read-enable transistor T_{REN} to the global source line GSLn connected to the source electrode of the read-enable transistor T_{REN}. The global source line GSLn is then charged.

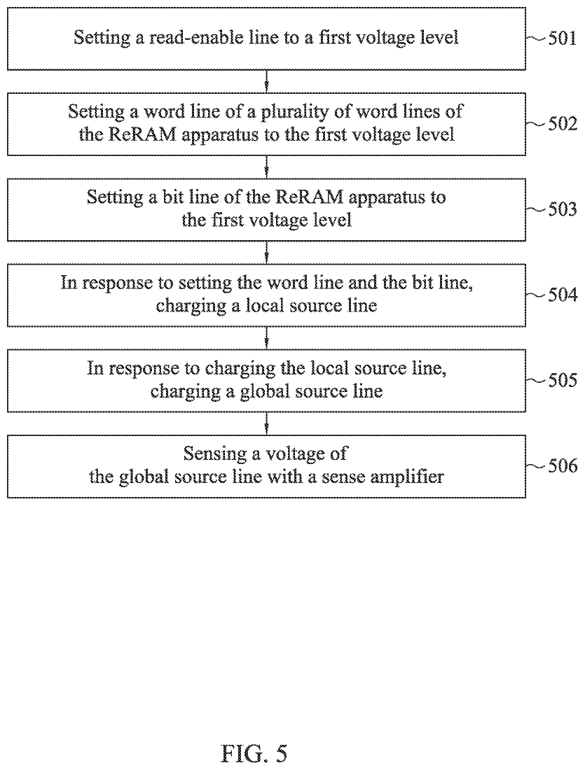

FIG. 5 is a flow chart of a method for operating a ReRAM apparatus in accordance with some embodiments of the present disclosure. In operation 501, a read-enable line is set to a first voltage level. In operation 502, a word line of a plurality of word lines of the ReRAM apparatus is set to the first voltage level. In operation 503, a bit line of the ReRAM apparatus is set to the first voltage level. In operation 504, in response to setting the word line and the bit line, a local source line is charged. In operation 505, in response to charging the local source line, a global source line is charged. Finally, in operation 506, a voltage of the global source line is sensed with a sense amplifier.

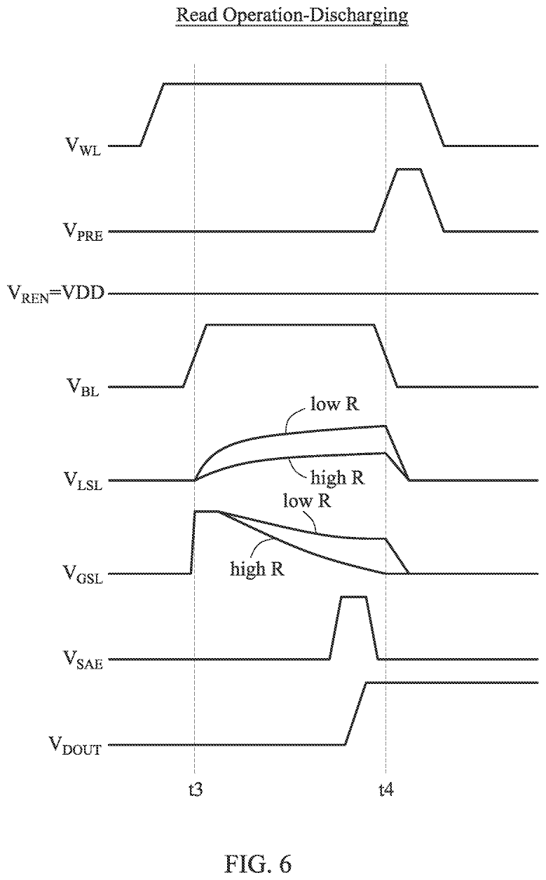

FIG. 6 is a time diagram of signals in a memory system in accordance with some embodiments of the present disclosure. FIG. 6 shows another read operation of a ReRAM apparatus 101 comprising a plurality of memory cells as shown in FIG. 2. In the read operation, first of all, the read-enable voltage V_{REN} of a read-enable line is set to a zero voltage level VSS. The read-enable line is connected to a drain electrode of a read-enable transistor of the ReRAM apparatus. The word line voltage V_{WL} of a word line of the plurality of word lines of the ReRAM apparatus is also set to a first voltage level VDD. The word line is connected to the gate electrode of a transistor of a memory cell of the plurality of memory cells. Then, at time t3, the bit line voltage V_{BL} of a bit line of the ReRAM apparatus is set to the first voltage level VDD. The bit line is connected to a first terminal of a resistor of a memory cell of the plurality of memory cells. A second terminal of the resistor is connected to the drain electrode of the transistor.

Since the word line is connected to the gate electrode of the transistor and the word line voltage V_{WL} is set to the first voltage level VDD, the transistor should be turned on in response to setting the word line and the bit line. A first current flows from the bit line through the resistor and the transistor to a local source line connected to a source electrode of the transistor and a gate electrode of the read-enable transistor. The local source line is then charged.

In some embodiments of the present disclosure, if the memory cell is in a low resistance state (low R), the first current should be relatively large so that the local source line voltage V_{LSL} of the local source line can be charged quickly. As the local source line voltage V_{LSL} being charged to a threshold voltage level of the read-enable transistor, the read-enable transistor is turned on. Therefore, in response to charging the voltage of the local source line, a second current flows from a global source line connected to the source electrode of the read-enable transistor to the read-enable line through the read-enable transistor. The global source line is then discharged. Finally, an enable voltage V_{SAE} of a sense amplifier is set to the first voltage level VDD. The global source line voltage V_{GSL} of the global source line is then sensed by the sense amplifier, and the sense amplifier outputs a data output voltage V_{DOUT}. Finally, at time t4, the bit line voltage V_{BL} of the bit line is set to zero and the preset voltage V_{PRE} of a preset line is set to the first voltage level VDD. The preset line is connected to the gate electrode of a preset transistor so that the preset transistor is turned on and creates a current path between the local source line and the global source line. Since the bit line is set to zero, both the local source line and the global source line are discharged to zero.

In some embodiments of the present disclosure, if the memory cell is in a high resistance state (high R), the first current should be relatively small so that the local source line voltage V_{LSL} of the local source line is charged slowly. As the local source line voltage V_{LSL} being charged to the threshold voltage level of the read-enable transistor, the read-enable transistor is turned on. Therefore, in response to charging the voltage of the local source line, the second current flows from the global source line connected to the source electrode of the read-enable transistor to the read-enable line through the read-enable transistor. The global source line is then discharged. However, since the local source line voltage V_{LSL} in the high resistance state is lower than the local source line voltage V_{LSL} in the low resistance state, the global source line voltage V_{GSL} of the global source line is discharged in a much slower speed. Then, an enable voltage V_{SAE} of a sense amplifier is set to the first voltage level VDD. The global source line voltage V_{GSL} of the global source line is then sensed by the sense amplifier, and the sense amplifier outputs a data output voltage V_{DOUT}. Finally, at time t4, the bit line voltage V_{BL} of the bit line is set to zero and the preset voltage V_{PRE} of a preset line is set to the first voltage level VDD. The preset line is connected to the gate electrode of a preset transistor so that the preset transistor is turned on and creates a current path between the local source line and the global source line. Since the bit line is set to zero, both the local source line and the global source line are discharged to zero.

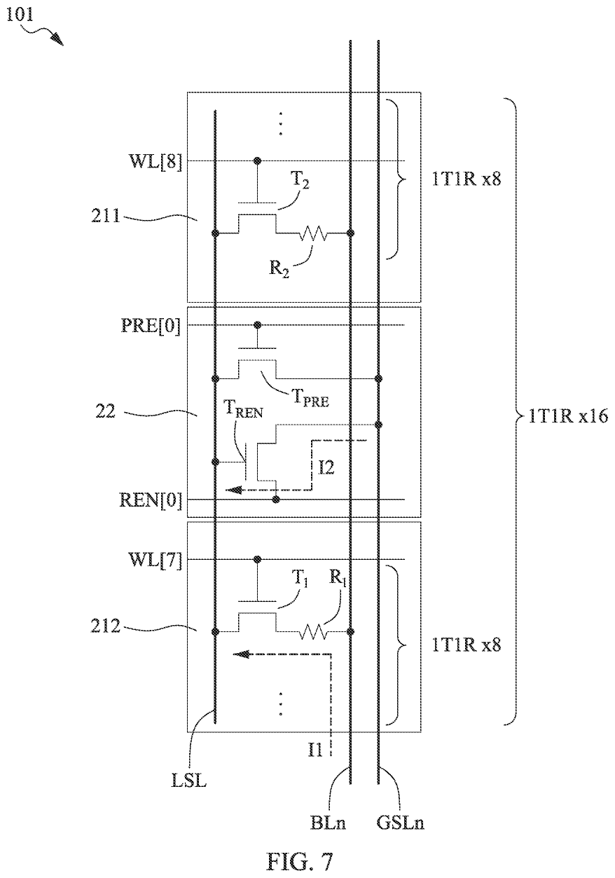

FIG. 7 is a schematic diagram of a ReRAM apparatus, in accordance with some embodiments of the present disclosure. FIG. 7 shows the current flows in the ReRAM apparatus 101 as shown in FIG. 2 during the read operation as mentioned in FIG. 6. Since the word line WL[7] is connected to the gate electrode of the transistor T1 and the word line voltage V_{WL} is set to the first voltage level VDD as shown in FIG. 3, the transistor T1 is turned on. The first current I1 flows from the bit line BLn through the resistor R1 and the transistor T1 to the local source line LSL connected to the source electrode of the transistor T1 and a gate electrode of the read-enable transistor T_{REN}.

Additionally, as the local source line voltage V_{LSL} being charged to a threshold voltage level of the read-enable transistor T_{REN}, the read-enable transistor T_{REN} is turned on. Therefore, in response to charging the voltage of the local source line LSL, the second current I2 flows from the global source line GSLn connected to the source electrode of the read-enable transistor T_{REN} to the read-enable line REN[0] through the read-enable transistor T_{REN}. The global source line GSLn is then discharged.

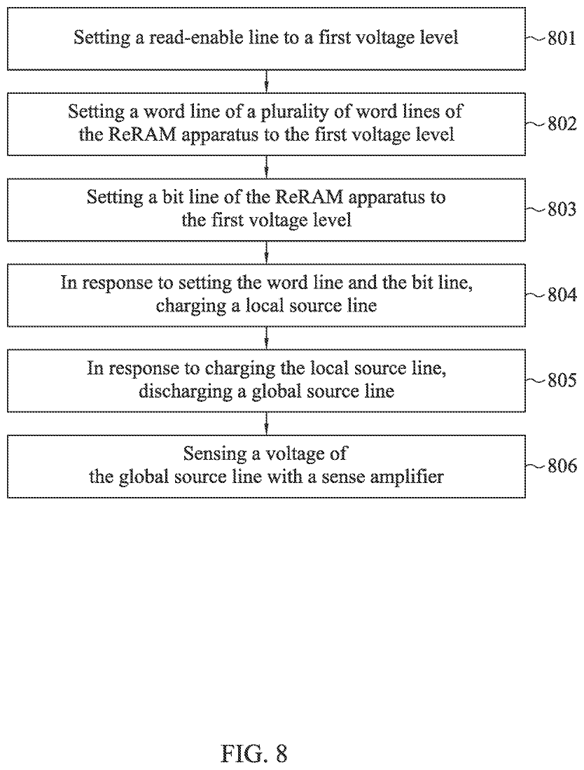

FIG. 8 is a flow chart of a method for operating a ReRAM apparatus in accordance with some embodiments of the present disclosure. In operation 801, a read-enable line is set to a first voltage level. In operation 802, a word line of a plurality of word lines of the ReRAM apparatus is set to the first voltage level. In operation 803, a bit line of the ReRAM apparatus is set to the first voltage level. In operation 804, in response to setting the word line and the bit line, a local source line is charged. In operation 805, in response to charging the local source line, a global source line is discharged. Finally, in operation 806, a voltage of the global source line is sensed with a sense amplifier.

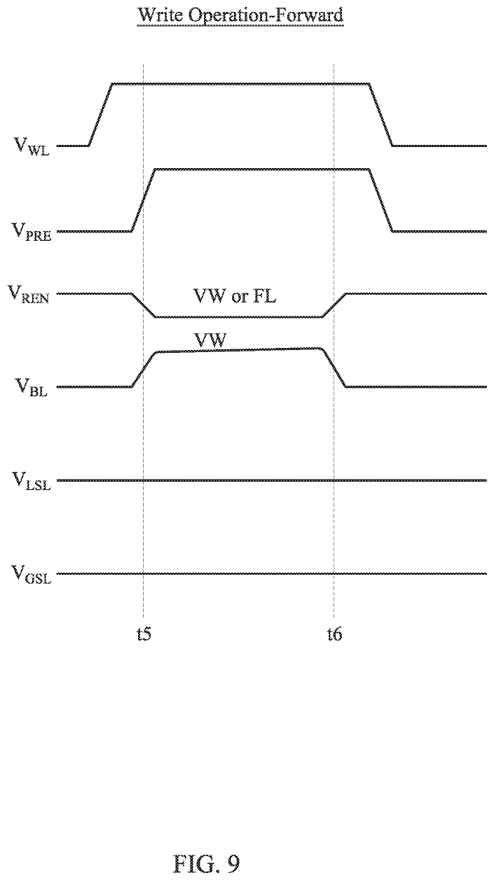

In some embodiments of the present disclosure, some resistive type memory devices need forward or reverse current for write operations to set the resistors in the resistive type memory devices to a high resistance state or a low resistance state. FIGS. 9-14 show such write operations.

FIG. 9 is a time diagram of signals in a memory system in accordance with some embodiments of the present disclosure. FIG. 9 shows a write operation of a ReRAM apparatus 101 comprising a plurality of memory cells as shown in FIG. 2. In the write operation, the global source line voltage V_{GSL} of the global source line is set to a first voltage level (e.g., zero) and the word line voltage V_{WL} of a word line of the plurality of word lines of the ReRAM apparatus is set to a second voltage level (e.g., VDD). The word line is connected to a gate electrode of a transistor of a memory cell of the plurality of memory cells. Then, at time t7, the preset voltage V_{PRE} of a preset line is set to the second voltage level. The preset line is connected to the gate electrode of a preset transistor. A read-enable line is set to a write voltage level VW or a high impedance (Hi-Z or floating (FL)). Then, the bit line voltage V_{BL} of a bit line of the ReRAM apparatus is set to the write voltage level VW. The bit line is connected to a first terminal of a resistor of a memory cell of the plurality of memory cells. A second terminal of the resistor is connected to the drain electrode of the transistor.

Since the word line is connected to the gate electrode of the transistor and the word line voltage V_{WL} is set to the first voltage level VDD, the transistor should be turned on. The local source line voltage V_{LSL} of the local source line and the global source line voltage V_{GSL} is both at zero since the local source line and the global source line are connected to each other through the turned-on preset transistor. A third current flows from the bit line through the resistor and the transistor to a local source line connected to the source electrode of the transistor and the gate electrode of the read-enable transistor. Accordingly, the resistor experience a forward current flow and is set to the high resistance state (high R). Finally, at time t6, the bit line voltage V_{BL} of the bit line of the ReRAM apparatus is set to zero so that the third current stops to complete the write operation.

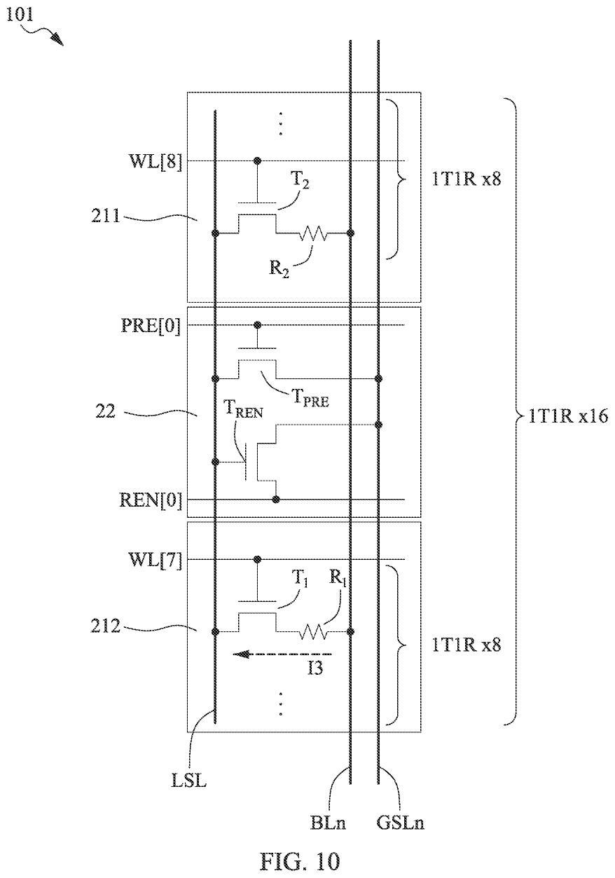

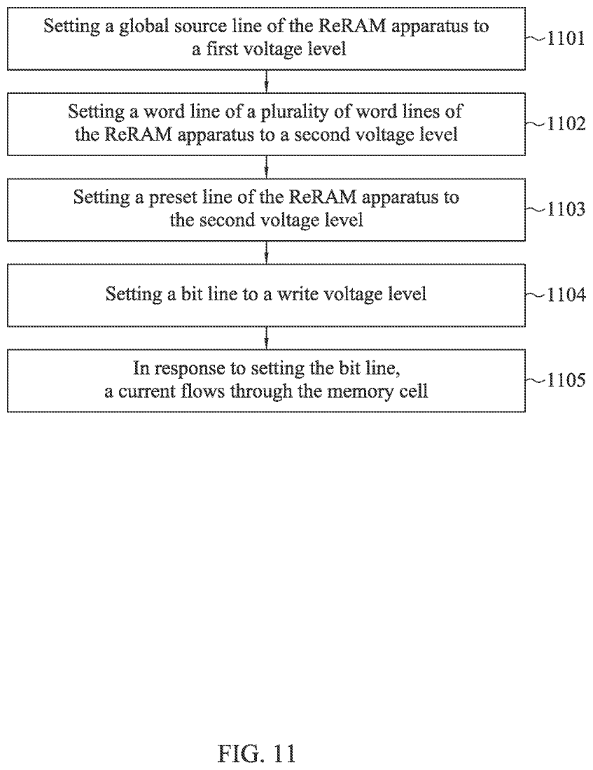

FIG. 10 is a schematic diagram of a ReRAM apparatus, in accordance with some embodiments of the present disclosure. FIG. 11 shows the current flows in the ReRAM apparatus 101 as shown in FIG. 2 during the read operation as mentioned in FIG. 9. Since the word line WL[7] is connected to the gate electrode of the transistor T1 and the word line voltage V_{WL} is set to the first voltage level VDD as shown in FIG. 9, the transistor T1 is turned on. The third current I3 flows from the bit line BLn through the resistor R1 and the transistor T1 to the local source line LSL connected to the source electrode of the transistor T1. Accordingly, the resistor experience a forward current flow and is set to the high resistance state (high R).

FIG. 11 is a flow chart of a method for operating a ReRAM apparatus in accordance with some embodiments of the present disclosure. In operation 1101, a global source line of the ReRAM apparatus is set to a first voltage level. In operation 1102, a word line of a plurality of word lines of the ReRAM apparatus is set to a second voltage level. In operation 1103, a preset line of the ReRAM apparatus is set to the second voltage level. In operation 1104, a bit line is set to a write voltage level. In operation 1105, in response to setting the bit line, a current flows through the memory cell. More specifically, the resistor in the memory cell experience a forward current flow and is set to the high resistance state (high R).

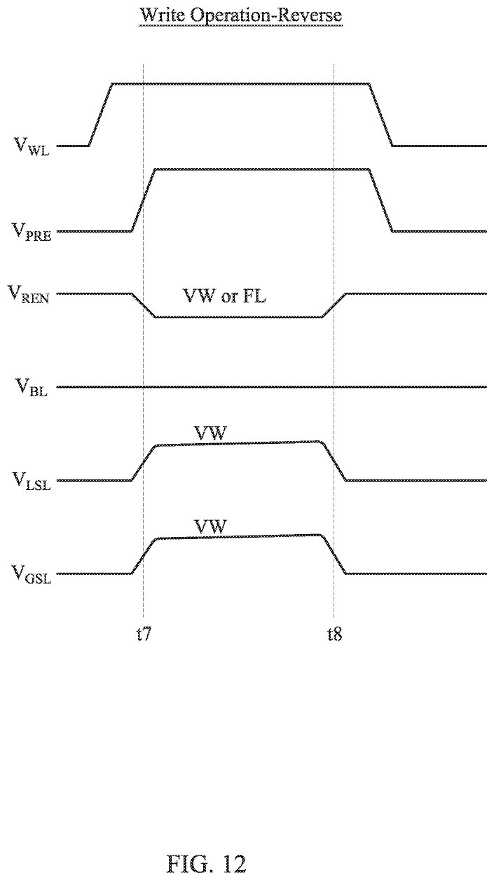

FIG. 12 is a time diagram of signals in a memory system in accordance with some embodiments of the present disclosure. FIG. 12 shows a write operation of a ReRAM apparatus 101 comprising a plurality of memory cells as shown in FIG. 2. In the write operation, the bit line voltage V_{BL} of the global source line is set to a first voltage level (e.g., zero) and the word line voltage V_{WL} of a word line of the plurality of word lines of the ReRAM apparatus is set to a second voltage level (e.g., VDD). The bit line is connected to a first terminal of a resistor of a memory cell of the plurality of memory cells. A second terminal of the resistor is connected to the drain electrode of the transistor. The word line is connected to a gate electrode of a transistor of a memory cell of the plurality of memory cells. Then, at time t7, the preset voltage V_{PRE} of a preset line is set to the second voltage level. The preset line is connected to the gate electrode of a preset transistor. A read-enable line is set to a write voltage level VW or a high impedance (Hi-Z). Then, the global source line voltage V_{GSL} of a global source line of the ReRAM apparatus is set to the write voltage level VW. The global source line is connected to the source electrode of the preset transistor. Since the gate electrode of the preset transistor is set to VDD, the preset transistor is turned on so that the local source line voltage V_{LSL} of the local source line is also set to the write voltage level VW.

Since the word line is connected to the gate electrode of the transistor and the word line voltage V_{WL} is set to the first voltage level VDD, the transistor should be turned on. A fourth current flows from the local source line through the resistor and the transistor to the bit line. Accordingly, the resistor experience a reverse current flow and is set to the low resistance state (low R). Finally, at time t8, the global source line voltage V_{GSL} of the global source line of the ReRAM apparatus is set to zero so that the fourth current stops to complete the write operation.

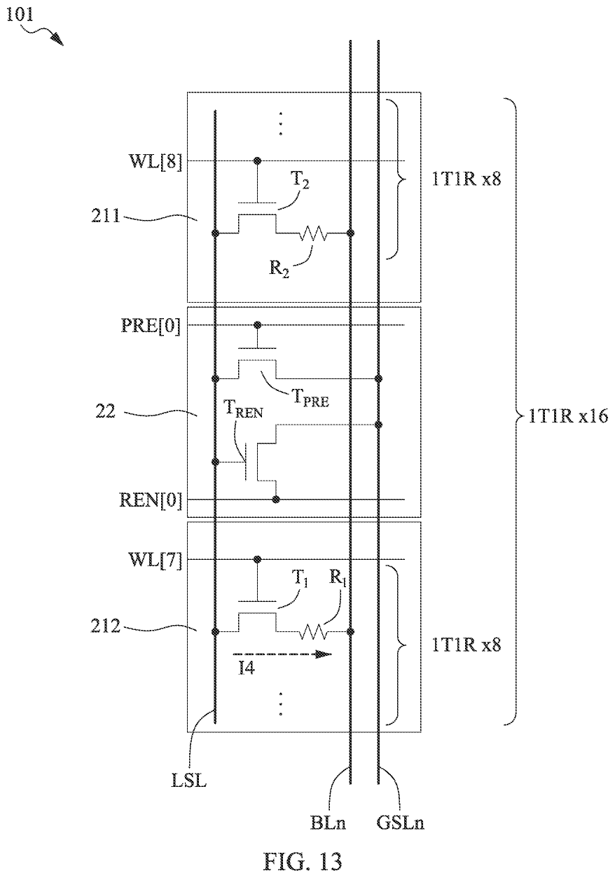

FIG. 13 is a schematic diagram of a ReRAM apparatus, in accordance with some embodiments of the present disclosure. FIG. 13 shows the current flows in the ReRAM apparatus 101 as shown in FIG. 2 during the read operation as mentioned in FIG. 12. Since the word line WL[7] is connected to the gate electrode of the transistor T1 and the word line voltage V_{WL} is set to the first voltage level VDD as shown in FIG. 12, the transistor T1 is turned on. The fourth current I4 flows from the local source line LSL connected to the source electrode of the transistor T1 through the resistor R1 and the transistor T1 to the bit line BLn. Accordingly, the resistor experience a reverse current flow and is set to the low resistance state (low R).

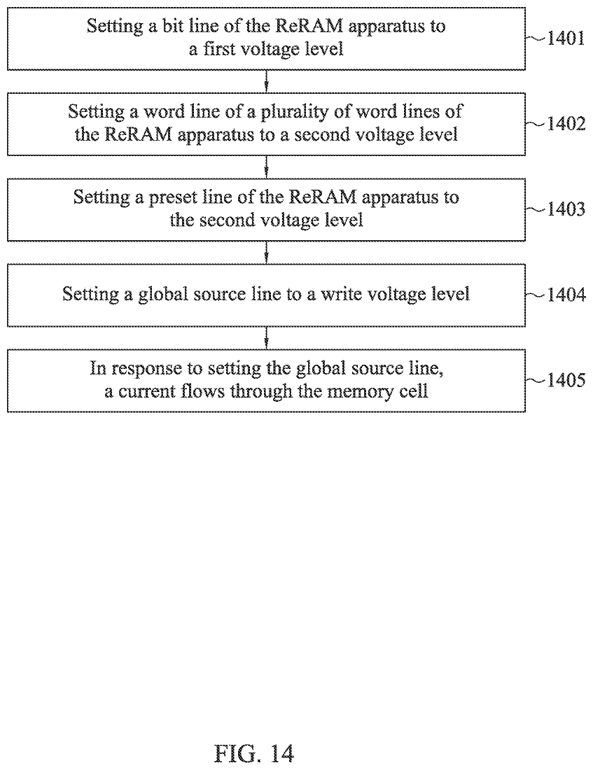

FIG. 14 is a flow chart of a method for operating a ReRAM apparatus in accordance with some embodiments of the present disclosure. In operation 1401, a bit line of the ReRAM apparatus is set to a first voltage level. In operation 1402, a word line of a plurality of word lines of the ReRAM apparatus is set to a second voltage level. In operation 1403. a preset line of the ReRAM apparatus is set to the second voltage level. In operation 1404, a global source line is set to a write voltage level. In operation 1405, in response to setting the global source line, a current flows through the memory cell. More specifically, the resistor in the memory cell experience a reverse current flow and is set to the low resistance state (low R).

According to the present disclosure, a memory structure with divided source lines is able to achieve higher readings speed and, in the meanwhile, the read and write operations can be accomplished without adding too many transistors. By merely adding two transistors (the preset transistor and the read-enable transistor) for each memory cell set (e.g., 16 memory cells), the local source lines and the global source lines can be operated efficiently. Therefore, the cell area penalty for the memory structure of the present disclosure is small. Moreover, as the global source lines sensed by the sense amplifiers are not directly driven by the small current of a memory cell, the required offset tolerance of the sense amplifiers can also be improved.

In accordance with some embodiments of the disclosure, a resistive random access memory (ReRAM) apparatus is provided. The ReRAM apparatus comprises: a plurality of memory cells, each of the memory cells comprises a transistor and a resistor; a bit line connected to a first terminal of the resistor of each of the memory cells; a local source line connected to a source electrode of the transistor of each of the memory cells; and a driving cell connected between the local source line and a global source line.

In accordance with some embodiments of the disclosure, a memory system is provided. The memory system comprises: a bit line, a global source line; and a plurality of ReRAM apparatuses. Each of the plurality of ReRAM apparatuses comprises: a plurality of memory cells, each of the memory cells comprises a transistor and a resistor, wherein a first terminal of the resistor of each of the memory cells is connected to the bit line, a local source line connected to a source electrode of the transistor of each of the memory cells, and a driving cell connected between the local source line and the global source line.

In accordance with some embodiments of the disclosure, a method for operating a ReRAM apparatus is provided. The method comprises: setting a read-enable line to a first voltage level, wherein the read-enable line is connected to a drain electrode of a read-enable transistor of the ReRAM apparatus; setting a word line of a plurality of word lines of the ReRAM apparatus to the first voltage level, wherein the word line is connected to a gate electrode of a transistor of a memory cell of the plurality of memory cells; setting a bit line of the ReRAM apparatus to the first voltage level, wherein the bit line is connected to a first terminal of a resistor of a memory cell of the plurality of memory cells, and wherein a second terminal of the resistor is connected to a drain electrode of the transistor; in response to setting the word line and the bit line, charging a local source line, wherein the local source line is connected to a source electrode of the transistor and a gate electrode of the read-enable transistor; in response to charging the local source line, charging a global source line connected to a source electrode of the read-enable transistor; and sensing a voltage of the global source line with a sense amplifier.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A resistive random access memory (ReRAM) apparatus, comprising:
a plurality of memory cells, each of the memory cells comprises a transistor and a resistor;
a bit line connected to a first terminal of the resistor of each of the memory cells;
a local source line connected to a source electrode of the transistor of each of the memory cells; and
a driving cell connected between the local source line and a global source line.

2. The ReRAM apparatus of claim 1, wherein the driving cell comprises a preset transistor, wherein a drain electrode of the preset transistor is connected to the local source line.

3. The ReRAM apparatus of claim 2, wherein a source electrode of the preset transistor is connected to the global source line.

4. The ReRAM apparatus of claim 2, wherein the driving cell further comprises a read-enable transistor, wherein a gate electrode of the read-enable transistor is connected to the local source line.

5. The ReRAM apparatus of claim 4, wherein a source electrode of the read-enable transistor is connected to the global source line.

6. The ReRAM apparatus of claim 1, wherein a drain electrode of the transistor of each of the memory cells is connected to a second terminal of the resistor.

7. The ReRAM apparatus of claim 1, further comprising a plurality of word lines, wherein a gate electrode of the transistor of each of the memory cells is connected to a respective one of the plurality of word lines.

8. The ReRAM apparatus of claim 1, wherein the plurality of memory cells are arranged into an array.

9. The ReRAM apparatus of claim 1, wherein the global source line is connected to a sense amplifier.

10. The ReRAM apparatus of claim 8, wherein the array are separated into a first group of memory cells and a second group of memory cells, wherein the driving cell is between the first group of memory cells and the second group of memory cells.

11. A memory system, comprising:
a bit line;
a global source line; and
a plurality of ReRAM apparatuses, each of the plurality of ReRAM apparatuses comprising:
a plurality of memory cells, each of the memory cells comprises a transistor and a resistor, wherein a first terminal of the resistor of each of the memory cells is connected to the bit line,
a local source line connected to a source electrode of the transistor of each of the memory cells, and
a driving cell connected between the local source line and the global source line.

12. The memory system of claim 11, wherein each of the driving cell comprises a preset transistor, wherein a drain electrode of the preset transistor is connected to the local source line of the respective ReRAM apparatus.

13. The memory system of claim 12, wherein a source electrode of each of the preset transistors is connected to the global source line.

14. The memory system of claim 12, wherein each of the driving cell further comprises a read-enable transistor, wherein a gate electrode of the read-enable transistor is connected to the local source line of the respective ReRAM apparatus.

15. The memory system of claim 14, wherein a source electrode of each of the read-enable transistors is connected to the global source line.

16. The memory system of claim 12, further comprising a plurality of preset lines, wherein each of the plurality of preset lines is connected to a gate electrode of the preset transistor of the respective ReRAM apparatus.

17. The memory system of claim 14, further comprising a plurality of read-enable lines, wherein each of the plurality of read-enable lines is connected to a drain electrode of the read-enable transistor of the respective ReRAM apparatus.

18. The memory system of claim 11, further comprising a plurality of word lines, wherein a gate electrode of the transistor of each of the memory cells is connected to a respective one of the plurality of word lines.

19. The memory system of claim 11, further comprising a sense amplifier, wherein the global source line is connected to the sense amplifier.

20. A method for operating a ReRAM apparatus comprising a plurality of memory cells, the method comprising:
setting a read-enable line to a first voltage level, wherein the read-enable line is connected to a drain electrode of a read-enable transistor of the ReRAM apparatus;
setting a word line of a plurality of word lines of the ReRAM apparatus to the first voltage level, wherein the word line is connected to a gate electrode of a transistor of a memory cell of the plurality of memory cells;
setting a bit line of the ReRAM apparatus to the first voltage level, wherein the bit line is connected to a first terminal of a resistor of a memory cell of the plurality of memory cells, and wherein a second terminal of the resistor is connected to a drain electrode of the transistor;
in response to setting the word line and the bit line, charging a local source line, wherein the local source line is connected to a source electrode of the transistor and a gate electrode of the read-enable transistor;
in response to charging the local source line, charging a global source line connected to a source electrode of the read-enable transistor; and
sensing a voltage of the global source line with a sense amplifier.
